(19) United States
(12) Patent Application Publication
(10) Pub. No.: US 2015/0077981 A1
(43) Pub. Date: Mar. 19, 2015

(54) PRINTED BATTERY FOR ELECTRONIC PERSONAL VAPORIZER

(71) Applicant: Cameron Lanning Cormack, Edmonton (CA)

(72) Inventor: Cameron Lanning Cormack, Edmonton (CA)

(21) Appl. No.: 14/284,549

(22) Filed: May 22, 2014

Related U.S. Application Data
(63) Continuation-in-part of application No. 14/028,205, filed on Sep. 16, 2013.

(51) Int. Cl. H01M 6/40; F21L 4/00; H05K 13/04

(52) U.S. Cl. CPC H01M 6/40; H05K 13/04; F21L 4/00; F21Y 2101/02
USPC 362/190; 429/124; 429/406; 29/874

(57) ABSTRACT

An electronic personal vaporizer is provided, including a shell having a flexible printed circuit board; and a printed battery printed on the flexible printed circuit board. The printed battery may be printed onto the flexible printed circuit board via application of inks to the flexible printed circuit board. The vaporizer may further include an electroluminescent light source printed on the flexible printed circuit board.

This application is a continuation in part of U.S. patent application Ser. No. 14/028,205 filed Sep. 16, 2013.

### FIELD

This invention relates to personal vapour inhaling units and more particularly to batteries for electronic personal vaporizers that simulate a cigarette or cigar.

### BACKGROUND

An electronic personal vaporizer is an alternative to smoked tobacco products, such as cigarettes, cigars, or pipes. Inhaled doses of vaporized flavour provide a physical sensation similar to smoking. However, because an electronic personal vaporizer typically uses electrical power to atomize a substance, no tobacco, smoke, or combustion is usually involved in its operation. A personal vaporizer may be battery powered for portability and to simulate the physical characteristics of a cigarette, cigar, or pipe. In addition, a personal vaporizer may be loaded with nicotine bearing substance and/or a medication bearing substance. The electronic personal vaporizer may provide an inhaled dose of nicotine and/or medication by way of the atomized and vaporized substance. Thus, personal vaporizers may also be known as electronic cigarettes, e-cigs, electronic cigar, e-cigar, or e-cigarettes. Electronic personal vaporizers may be reusable, with replaceable and refillable components, or may be disposable. Electronic personal vaporizers may be used to administer flavours, medicines, drugs, or any substances that are vaporized and then inhaled.

Typical common components of an electronic personal vaporizer include a light emitting diode, a switch, a battery, liquid cartridge, an atomizer, a tip, and conductors. Typically these components are fitted inside a shell that may resemble the cylindrical appearance of a traditional tobacco cigarette or cigar. The shell is typically a tube made from metal or plastic that approximates the outside diameter and length of a traditional tobacco cigarette or cigar. The shell may also be referred to as a housing, body, tube, enclosure, casing, case, or container. The liquid cartridge is a self-contained structure which typically contains the substance that is to be vaporized. Depending on the design of the electronic personal vaporizer, the cartridge may be coupled to the shell or integral to the shell. Such factors that influence the cartridge design are commonly based on whether or not the electronic personal vaporizer is disposable or reusable, in which case it must be possible to replace or refill the cartridges.

The assembly procedure of the electronic personal vaporizers generally requires delicate human labour since the shell is relatively small in size and the components must be placed inside the shell tube by way of the small open ends. Furthermore many end-caps, seals, bulkheads and components require friction fits to maintain their position inside the shell. Typically the internal components are assembled with human labour prior to their insertion within the shell. Forces manually applied to the internal assembly during insertion to overcome the required friction fits can cause damage to the delicate components and their soldered connections. Additionally, some loose fitting internal components, such as the battery, can also cause damage during shipping and handling of the finished product. The addition of glue to the internal assembly is usually required to prevent unwanted movements of the components.

Bulkheads and seals are employed inside the shell of the electronic personal vaporizer to limit potential contamination of different areas within. One particularly important seal is the bulkhead separating the battery from the atomizer It is very undesirable to have a damaged battery leak some of its harmful substances into the atomizer area. Although materials exist that can seal well to the shell surface, an inherent problem still exists for this bulkhead. The wires from the battery side of the bulkhead need to pass through to the atomizer Therefore by nature of current designs, the bulkhead must be breached with apertures for the wires to pass through thus exposing the electronic personal vaporizer to an elevated risk associated with bulkhead leaks.

Currently some mechanical designs are employed which entail complex bulkhead configurations of machined parts, isolators, glands, seals, and sealant to reduce leakage caused from the wire passageways. These current designs create complexity, are costly, and deter current designs from utilizing more wires to pass through the bulkhead for additional functionality.

Current designs of electronic personal vaporizers include a stand-alone battery. Typically the battery represents the majority of the material costs. Additionally, the battery requires manual soldering and once electrically connected to the vaporizer, must then be pressed into the cylindrical shell during normal assembly procedures. This procedure can produce a high number of unit failures due to the delicate nature of the soldered connections and the insertion force required to position the typical stand-alone battery into position within the tube shell.

Another typical component of current electronic personal vaporizers is a LED (Light-Emitting Diode). The LED is soldered to the circuitry of the vaporizer thus presenting another possible point for a connection failure. Similarly to the battery, the LED is typically manually soldered.

It is therefore, desirable to have an electronic personal vaporizer and method of fabricating same that: requires less labour to assemble, holds components, such as the LED and battery, firmly in position, allows well sealed bulkheads, allows for many wire pathways across bulkheads, allows easy positioning of internal components, and allows for high level of automation in the assembly process.

### SUMMARY

The present invention overcomes the limitations of the prior art by employing the use of a flexible printed circuit board as the shell of the electronic personal vaporizer. A flexible printed circuit board in its purest form is an array of conductors bonded to a thin dielectric flexible film. Flexible Printed Circuit Boards (FPCB) can also be referred to as Flex Circuits, flexible printed circuits (FPC), flexible circuitry, and flexible printed circuitry. Most flexible circuits are passive wiring structures that are used to interconnect electronic components such as integrated circuits, resistors, capacitors and the like. The dielectric layer is usually polyimide (PI) or polyester (PET), but other materials can be used such as polyethylene napthalate (PEN), polyetherimide (PEI), paper and other cellulose based materials, along with various fluoropolymers (FEP) and copolymers. The circuit can also be easily bonded to a curved surface or formed via elastic and plastic deformation to any shape.

The internal components of an electronic personal vaporizer are interconnected to the FPCB while the FPCB is in a form that allows easy access for this process. After the components are affixed to the FPCB, the FPCB can be deformed into a shape desired for the shell. One embodiment of the present invention is the interconnected FPCB that is elastically deformed into a tubular shell of an electronic personal vaporizer by rolling. The elastic deformation of the FPCB can be stabilized so that it will retain its shape once the external forces that deformed it are removed. The shape stabilization can be achieved by means such as bonding. Bonding of the FPCB can be achieved through chemical, mechanical, or thermal processes. Some means of bonding are achieved through the use of adhesive tapes, stickers, and labels applied to the deformed FPCB to resist the natural spring back movement characteristic of elastic deformation. Additionally, other bonding means can be employed such as melting of the FPCB substrate to itself or other structures. Such thermal bonding operations can be achieved by means of ultrasonic welding, high frequency welding, hot gas welding, friction welding, spin welding, laser welding, contact welding, hot plate welding, and heat sealing to name but a few.

Furthermore the FPCB can also be shaped by plastic deformation thus reducing and possibly eliminating the need for shape stabilization. Plastic deformation of the FPCB can be achieved by exceeding the yield strength of the substrate during deformation. Additionally, the FPCB substrate can be thermally moulded to achieve deformation. Plastic deformation techniques of the FPCB may still require shape stabilization depending on desired characteristics of shape and rigidity of the final deformed shape sought.

Typically the FPCB in its natural form would have a generally flat shape presenting itself more akin to the typical rigid printed circuit board. The components are typically interconnected to the FPCB while in the generally flat shape however deforming particular areas of the naturally shaped FPCB prior to interconnecting may have advantages. Bonding components by way of soldering to the FPCB while it is generally flat will cause the affected areas to remain in its natural shape while deformation of the rest of the FPCB occurs. To overcome this potentially undesirable effect, it would be beneficial to deform the areas where the soldering will be prior to soldering, while leaving a sufficient amount of the FPCB in its natural shape to allow easy access for interconnecting. Once the area is deformed closely to its desired final shape, the components can be soldered to the FPCB thus assuring the shape of the solder bonded area will match to the final overall deformed shape of the FPCB.

There are many structures of FPCB's that could be used in the manner taught by this invention. Some of the FPCB structures include: single-sided, double access or back bared, sculptured, double-sided, multilayer, rigid-flex, and polymer thick film flex circuits. The double-sided and multilayer FPCB structures resolve cross bulkhead wiring issues with the least amount of complexity. A FPCB formed shell for an electronic personal vaporizer can have components on the inside of the shell and on both sides of a bulkhead. In many situations the circuitry of the electronic personal vaporizer may need to interconnect the components across the bulkhead. In this case the conductors printed on the inside of the FPCB, on one side of the bulk head, can pass through the substrate by means of through-holes and vias to connect to conductors printed on the exterior side of the shell. These conductor pathways can then transverse the bulkhead. These pathways, commonly known as traces, can terminate on the outside of the shell or by means of through-holes and vias can pass through the FPCB substrate once again into the interior of the shell where traces can be used to further the conductive pathways. In essence the electrical circuit is bypassing the bulkhead on the exterior of the shell, as to leave the bulkhead intact with no points of penetration through the bulkhead. Since the traces on the exterior are very thin, there is insignificant protrusion of the conductive pathways above the exterior surface of the electronic personal vaporizer shell of the current invention. Furthermore, exterior finishing of the electronic personal vaporizer can further conceal and protect the circuitry present on the exterior surface of the FPCB shell. The bulkhead can be constructed from material compatible with the substrate of the FPCB and with known bonding technologies. The bulkhead can be bonded with the interior of the FPCB shell by means of adhesives, solvent welding, thermal welding and others. A bulkhead bonded to the FPCB shell that is not breached provides a secure and reliable barrier to keep areas isolated from one another.

Components can be affixed to either side of the FPCB thus allowing switches and Light Emitting Diodes (LEDs) to be soldered to the outside of a formed shell shape as easily as they can be affixed to the inside. Components on the inside of a FPCB shell would generally be affixed before final formation of the FPCB shell. Independently, components on the exterior of a FPCB shell could be affixed prior or after the final formation of the FPCB shell of the present invention.

The switch is a common component of an electronic personal vaporizer. The switch can be used to control the power supplying the atomizer or the switch can signal a controller circuit. There are many types of switches that can be used with the present invention. The membrane switch is a type of switch constructed from FPCB and is both compact and low profile. The membrane switch can be easily integrated into the FPCB shell of an electronic personal vaporizer at marginal cost. There is a minimum amount of FPCB material required to form a shell of a specific shape and size. However, additional material can be allotted in the FPCB which would provide overlap when forming the shell. This overlap could be used for shape stabilization as well as providing the dome element required for a membrane switch.

Furthermore, graphics and artwork can be printed onto the overlapping portion of the FPCB and after finalized formation of the shell; the graphics are viewable as the exterior of the finished form of the FPCB shell. The overlap can be bonded to the FPCB or the FPCB shell can be bound with transparent materials such as tape, plastic wrap, shrink wrap, or plastic tubing to name but a few.

Alternatively the FPCB shell shape can be wrapped with a sticker, label, decal, or tape that has graphics and artwork displayed. This method provides visual elements to the shell as well as provides stabilization to the shell shape.

Furthermore, the FPCB shell can be inserted into other non-FPCB shells or casings. These hard exteriors may have additional electrical components integrated within such as displays, buttons, and controllers to name but a few. The FPCB shell of the present invention can employ electrical contacts on its exterior surface that can couple to electrical contacts on the interior of the more rigid non-FPCB outer shell. The contact coupling allows control of the electrical components inside the FPCB shell via interactions with the outer non-FPCB shell. The non-FPCB outer shell can be comprised of material such as cardboard, plastic, and metal to name but a few.

Another aspect of the present invention is the incorporation of an integral printed battery and integral printed EL (electroluminescent) light such as an OLED (Organic Light-Emitting Diode). The printed battery and OLED can be printed by various means such as screen printing, offset lithography, transfer-printing, gravure, flexography, and inkjet to name but a few.

The printing of the battery is a process of applying chemical compounds to a substrate in the form of inks that include the different components required for a battery. Some typical components are current collector, anode, cathode, electrolyte, and separator.

Inks can be formulated to possess the required properties of the battery components. The application of these specially formulated inks in layers mostly on top of each other produce the mechanical structure of the battery.

Electroluminescent light sources are fabricated using either organic or inorganic electroluminescent materials. The active materials are generally semiconductors of wide enough bandwidth to allow exit of the light. A typical OLED is composed of a layer of organic EL materials situated between two electrodes, the anode and cathode, all deposited on the FPCB substrate. Generally speaking, at least one of the electrodes should be optically transparent to allow the light to escape the layered structure. Typically it is the anode that possesses this optically transparent characteristic.

Printing of the battery and EL light source, such as an OLED, onto the FPCB can be accomplished by means of automated processes. The material and labour costs for manufacturing the printed components is significantly less than the stand-alone counterparts used in the typical current state of the art. Overall production quality can be increased by employing automated machinery and processes in place of the manual labour.

### BRIEF DESCRIPTION OF THE DRAWINGS

FIG. 1 is an isometric view of seven common internal components found inside a disassembled electronic personal vaporizer.

FIG. 2 is an isometric view of a double sided flexible printed circuit board in a flat orientation.

FIG. 3 is an isometric view of an embodiment of the present invention showing a flexible printed circuit board with common internal components of an electronic personal vaporizer affixed thereon. Some internal hidden features are portrayed.

FIG. 4 is an orthographic top view of an embodiment of the present invention in which hidden features are portrayed with dotted lines.

FIG. 5 is an orthographic view of the proximal end of an embodiment of the present invention.

FIG. 6 is an orthographic view of the proximal end of an embodiment of the present invention. Accompanying this view is also a magnified sectional view of the area denoted with ‘A’.

FIG. 7 is an isometric view of an embodiment of the present invention wherein the bottom of the electronic personal vaporizer is exposed for viewing.

FIG. 8 is an isometric view of an embodiment of the present invention wherein the top of the electronic personal vaporizer is exposed.

FIG. 9 is an orthographic view of the proximal end of an alternate embodiment of the present invention.

FIG. 10 is an isometric view of an alternate embodiment of the present invention. Some internal hidden features are portrayed on the exterior.

FIG. 11 is a view of the top side of an alternative embodiment of the invention.

FIG. 12 is a view of the bottom side thereof.

FIG. 13 is a flowchart demonstrating a method of manufacturing the present invention.

FIG. 14 is an isometric view of an outer casing for use with an embodiment of the invention.

FIG. 15 is an isometric view of an embodiment of the present invention inserted into an outer casing. A partial hidden feature view is provided of the proximal end of the embodiment for visual reference.

FIG. 16 is an isometric view of an embodiment of the present invention with an integral printed battery.

FIG. 17 is an orthographic view of the distal end of an embodiment of the present invention with an integral printed battery. The membrane switch dome (40) is not depicted.

### DETAILED DESCRIPTION

In this document, the following terms will have the following meanings:

“stabilize” or “stabilizing” means to make, maintain or hold, firm or steadfast;

“shell” means a covering, housing, body, tube, enclosure, casing, case, or container;

“electronic personal vaporizer” means a generally cigar or cigarette shaped apparatus designed to allow users to inhale vapour, which may contain a substance, such as nicotine, through one end of the apparatus. Electronic personal vaporizers are also commonly known as electronic cigarettes, e-cigs, electronic cigars, e-cigars, or e-cigarettes.

“flexible printed circuit board” or “FPCB” means an array of conductors bonded to a thin dielectric flexible film, and are also referred to as flex circuits, flexible printed circuits (FPCs), flexible circuitry, and flexible printed circuitry.

“bond” means to bind, fasten, confine or hold together, and may be by chemical, mechanical or thermal means.

“bulkhead” means a partition to prevent the passage of fluid, and may also be referred to as a barrier, hindrance, obstruction, obstacle or baffle.

“ink” means printed electronics inks (also known as “functional inks”). The ink may be formulated for a number of purposes, including (1) optical, electrical, and mechanical properties such as sealing, isolating, protecting, and preserving underlying ink layers and substrates; (2) conductive, insulating, and resistive properties; (3) thick film or thin film properties; (4) to contain organic chemicals, inorganic chemicals, polymers, epoxies, nanoparticles, nanofibers, and/or biological materials; (5) to have chemistries of type water base, ultraviolet cures, or solvent bases; (6) for adhesion characteristics in relation to the substrate they are printed on; or (7) for characteristics relating to viscosity, compatibility, wetting properties, bendability, stretch ability, water resistance, and cost.

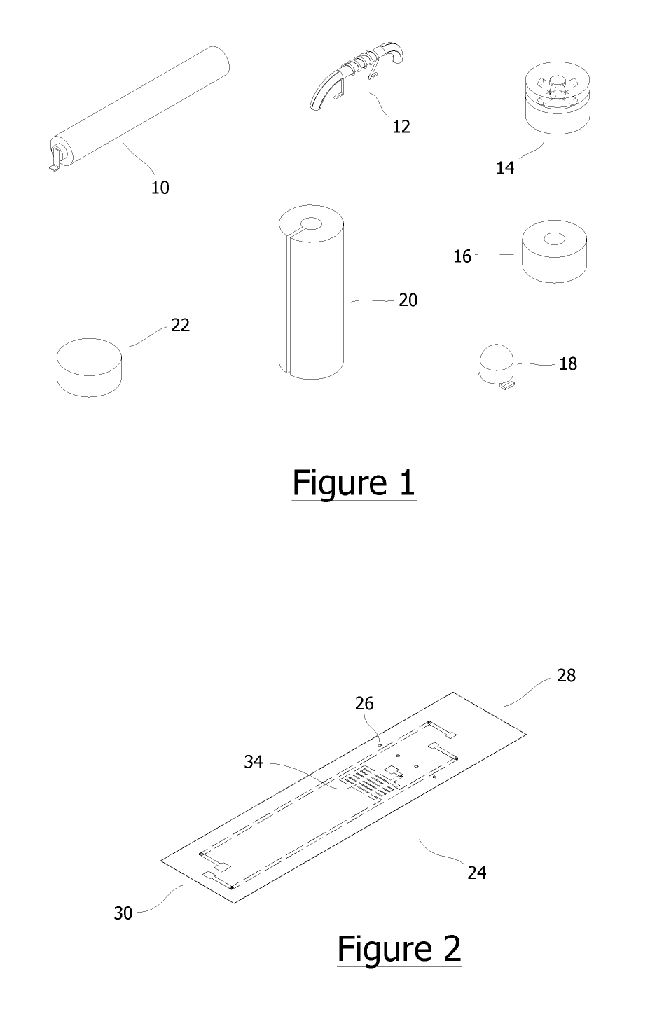

FIG. 1 illustrates common internal components used in the construction of an electronic personal vaporizer. These common components are: a power source, such as a battery 10, an atomizer 12, which may include one or more heating elements, an LED indicator light 18, a liquid container, such as liquid absorbent wadding 20, a bulkhead 14 to separate battery 10 from the atomizer 12 area, a distal end seal bulkhead 22 at the distal end of the vaporizer with respect to the user's mouth, and a proximal end seal bulkhead 16 at the proximal end of the vaporizer with respect to the user's mouth. Many of these components are electrical, in that they require or provide electrical power. These include the atomizer 12, the LED indicator light 18 and the battery 10.

The absorbent wadding 20 is positioned in contact with the atomizer 12 assembly so as to provide solution that is absorbed in the wadding 20 to the atomizer 12 via a wicking action. The proximal end seal bulkhead 16 has an airway aperture 44 to allow air and vapour to be drawn out of the atomizer area via suction produced by the vaporizer user. Bulkhead 14 has an airway aperture 46 that penetrates axially into the bulkhead but then terminates radially out of the bulkhead. Bulkhead 14 does not have an axial breach.

Referring to FIG. 2, a flexible printed circuit board is shown with electrical traces on the top and bottom sides. This embodiment illustrates a single wrap FPCB 24 configuration. A single wrap FPCB has only enough width of material to be rolled into a single layer around the components. This further means that the axial edges of the FPCB will butt together rather than overlap, as can be seen in detail in FIG. 6. The butting of the axial edges of the FPCB 24 produces a butt seam 32.

Again referring to FIG. 2, various elements can be incorporated into the FPCB such as airway apertures 26 that allow airflow into the atomizer 12 area and a membrane switch contact array 34 which is used to activate the atomizer 12. The distal end 30 and proximal end 28 of the single wrap FPCB 24 are illustrated for reference. Switch contact array 34 may be an electrical component of the vaporizer.

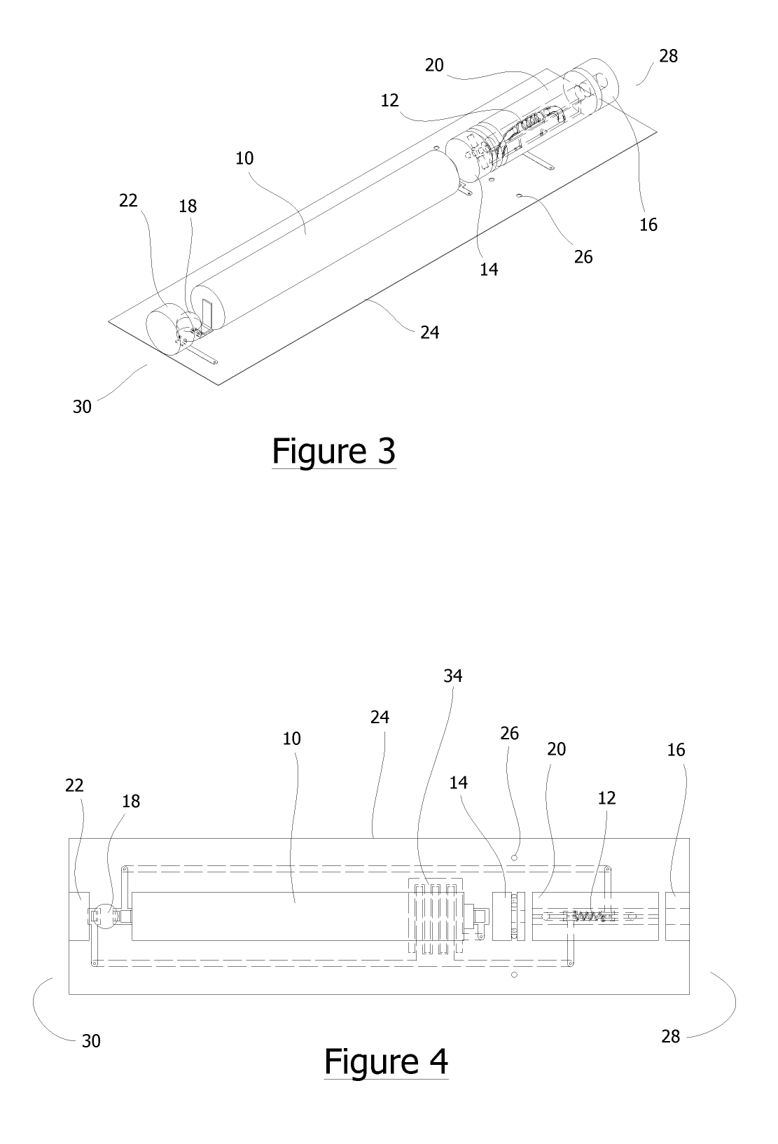

FIG. 3 shows the single wrap FPCB 24 with the common components affixed into position. The components can be easily positioned while the single wrap FPCB 24 is in its natural and flat orientation. The axial portion of airway apertures 46 of the bulkhead 14, absorbent wadding 20, and proximal end seal bulkhead 16 are aligned. Radial portion of airway apertures 46 of the bulkhead 14 are also aligned with the FPCB airway apertures 26.

FIG. 4 shows both traces and components on the top side of the FPCB as well as hidden traces that are on the bottom side of the FPCB. It is apparent that the components are affixed to the FPCB in alignment. This alignment is depicted as an embodiment of the invention but is not required to be in the particular order shown. The components can be affixed in various positions on the FPCB such that the rolling of the single wrap FPCB 24 into a tubular shell will bring the components back into final alignment.

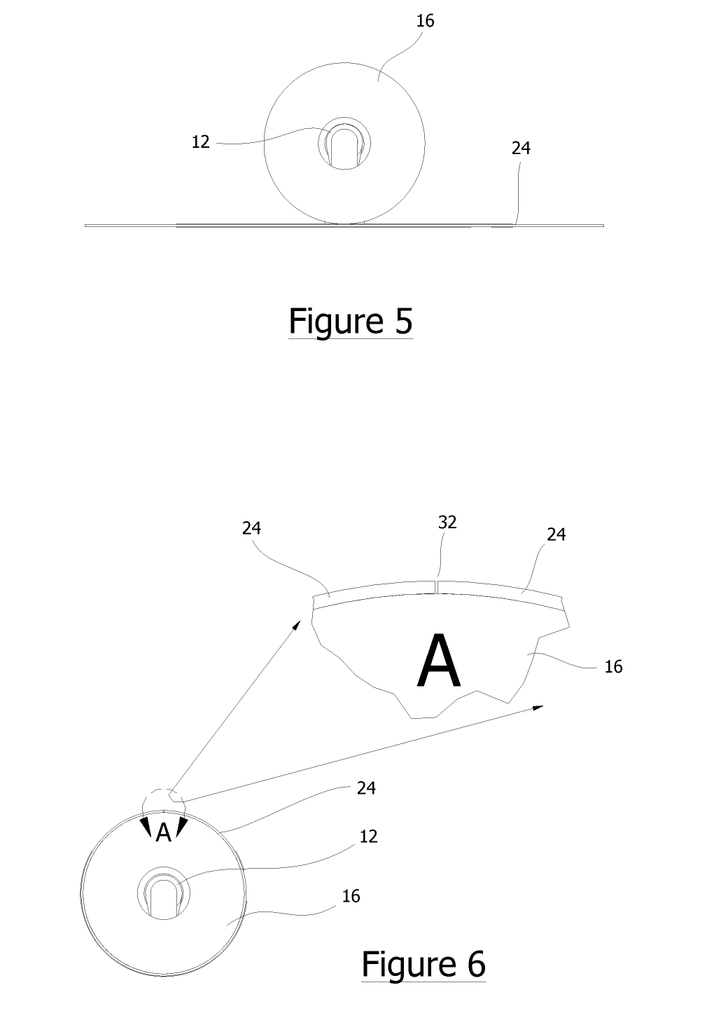

FIG. 5 is a proximal end view of the single wrap FPCB 24 with common components affixed. The atomizer 12 is visible within the airway aperture 44 of the proximal end seal bulkhead 16. The single wrap FPCB 24 can be seen in its natural flat position and provides easy access for component placement.

FIG. 6 is a proximal end view of the single wrap FPCB 24 with common components affixed. The atomizer 12 is visible within the airway aperture 44 of the proximal end seal bulkhead 16. The single wrap FPCB 24 can be seen deformed into a tubular shape around the common components. A magnified view shows the butt seam 32 of the FPCB shell of this embodiment.

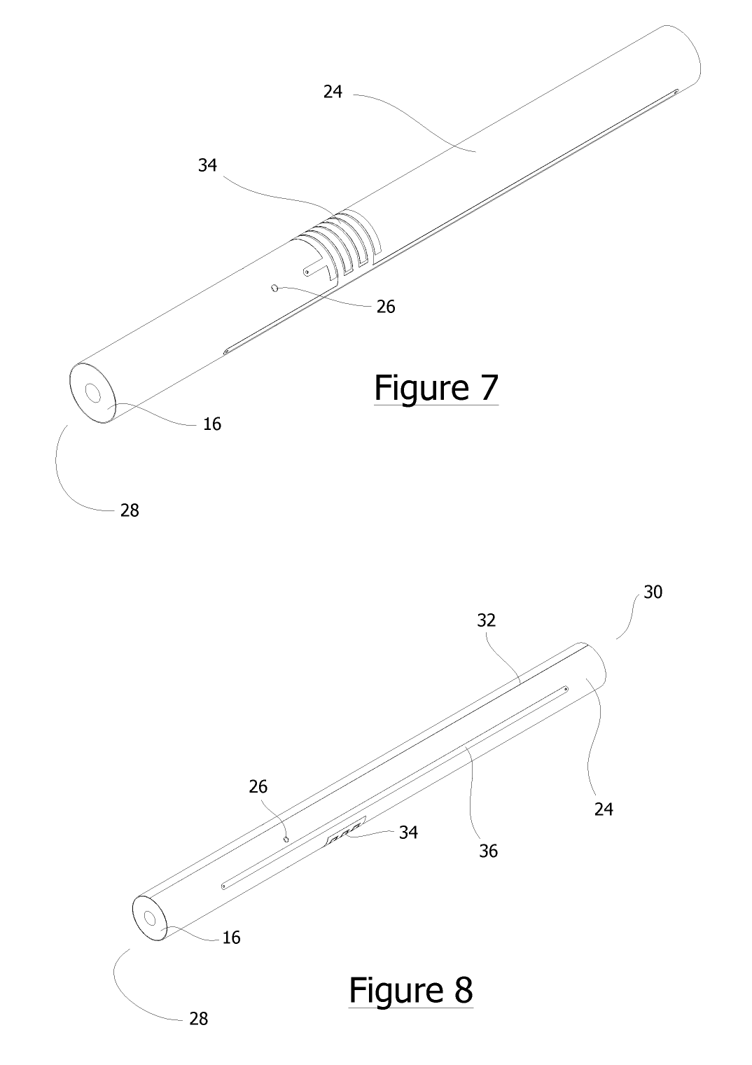

FIG. 7 and FIG. 8 show the single wrap FPCB 24 shell embodiment in an isometric view as to clearly show the features of the shaped shell. FIG. 7 and FIG. 8 show opposite sides of the FPCB shell 24. It can be clearly seen that the top side and bottom side of the single wrap FPCB 24 in its natural orientation become the inside and outside, respectively, of the FPCB 24 shell after it is deformed into a tubular shape. Bulkhead 14 is situated internally between airway apertures 26 and membrane switch contact array 34. The bulkhead 14 does not need to be breached with conductor pathways or passage ways since traces on the inside are connected to traces on the FPCB shell exterior. These radially external traces 36 can transverse the internally located bulkhead 14 thus providing conductive pathways from one side of the cylinder defined by the bulkhead 14 to the other side without breaching the bulkhead 14.

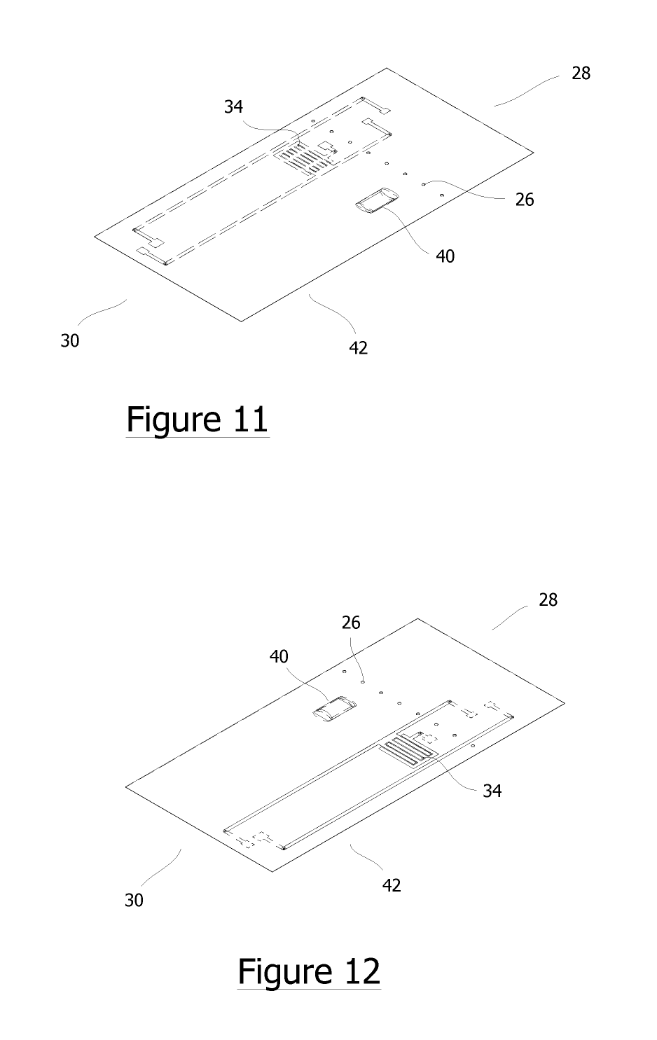

FIG. 11 and FIG. 12 show the top side and bottom side, respectively, of another embodiment of the present invention. A multi-wrap FPCB 42 is shown with integral membrane switch dome 40. The FPCB of the present embodiment has sufficient width to overlap itself when deformed into a tubular shape. The additional FPCB material provides benefits such as improved seam integrity and sealing characteristics, increased shell rigidity, integral graphics, integral membrane switch dome 40, integral shell stabilization means, amongst others.

The conductive surface of the membrane switch dome 40 of FIG. 11 is positioned above the membrane switch contact array 34 of FIG. 12 when the multi-wrap FPCB 42 is deformed by overlapping the a first end 50 of multi wrap FPCB over the second end 52 during wrapping. The alignment of the membrane switch assembly can be seen in FIG. 10. The switch works by pressing the membrane switch dome 40 which contains a conductor on its surface against the membrane switch contact array 34. The dome conductor shorts at least two conductors in the array which then completes a circuit.

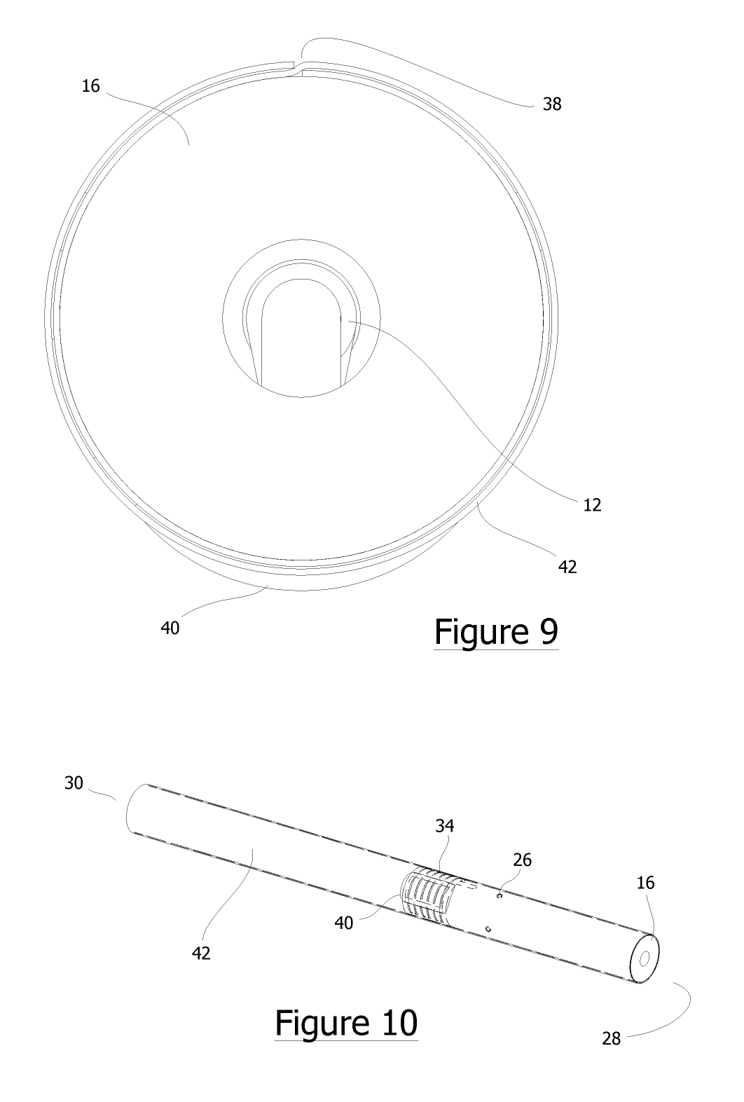

FIG. 9 is a proximal end view of the multi-wrap FPCB 42 with common components affixed. The atomizer 12 is visible within the airway aperture of the proximal end seal bulkhead 16. The multi-wrap FPCB 42 can be seen deformed into a tubular shape around the common components. Also shown is the overlapped butt seam 38 of the FPCB shell of this embodiment. Although this embodiment depicts a FPCB shell comprised of two layers of FPCB material, any number of layers is possible and desired FPCB shell characteristics would be a factor for number of layers. The membrane switch dome 40 can also be seen protruding from the circular FPCB shell body.

The FPCB of these described embodiments would be deformed into tubular shapes via elastic deformation. Therefore there would be a tendency for the FPCB to unwrap and return to its natural orientation once the deformation forces have been removed. Form stabilization means would be required to prevent the FPCB from unwrapping. Such means for the single wrap FPCB 24 and multi-wrap FPCB 42 would be external elements such as stickers, decals, tape, plastic wraps, heat shrink, to name but a few. However the multi-wrap FPCB 42 could additionally be stabilized with adhesives and thermal means applied to the overlapping areas of the FPCB.

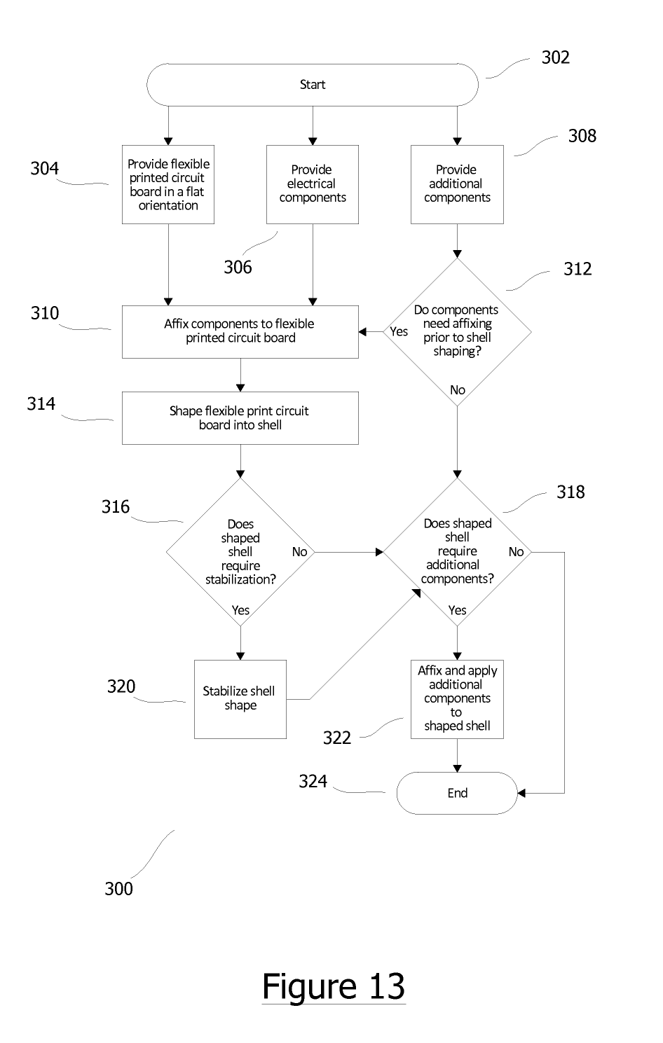

FIG. 13 illustrates an embodiment of a process 300 of manufacturing an electronic personal vaporizer which comprises a FPCB shell. The process begins (step 302) with the provision of a FPCB (step 304), electrical components (step 306) and/or non-electrical components (step 308). According to the manufacturing process described herein at step 312 some components may be affixed prior to deforming (step 310) or after deformation of the FPCB as needed (steps 318 and 322). The FPCB is shaped (step 314) and, if needed at step 316, stabilized (step 320) prior to addition of more components to the shaped shell (step 322). The process is then complete (step 324).

The liquid substance is also a component of the electronic personal vaporizer and may be applied to the device before or afterwards of the shell formation. The preferred method of applying the liquid would be to inject it into the liquid containment area after the FPCB shell is formed. Injecting the liquid afterwards minimizes the contamination of liquid into the automated assembly equipment and FPCB shell surfaces prior to forming and stabilizing.

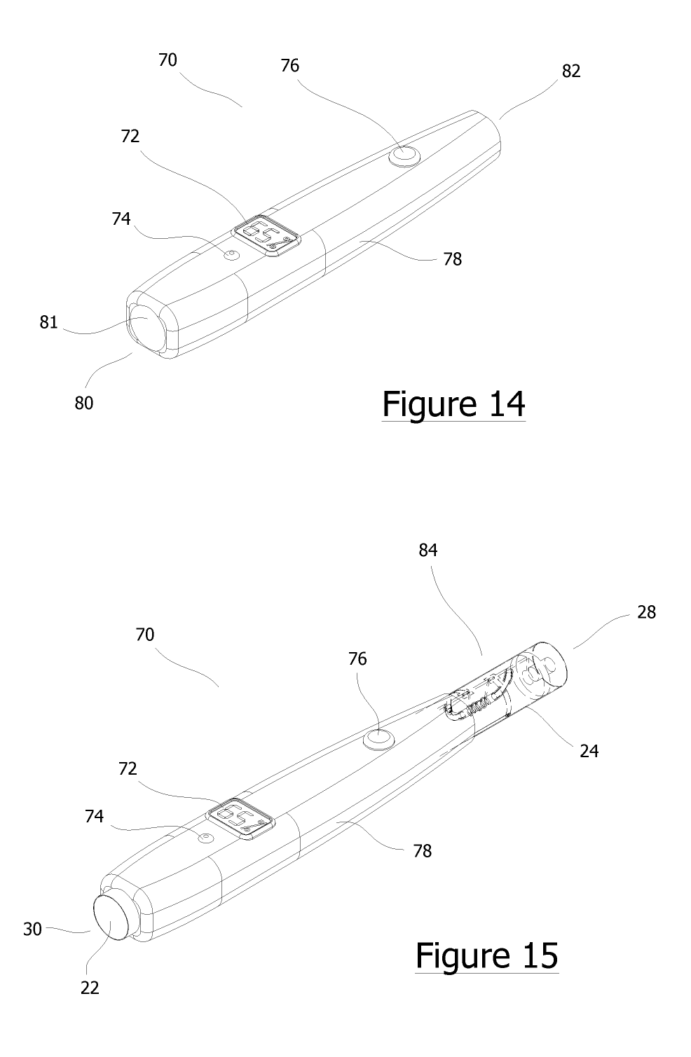

As shown in FIGS. 13 and 14, FPCB shell 24 can be inserted into and affixed to non-FPCB shells or casings 70. FIG. 15 display a portion 84 of the personal vaporizer that would normally be hidden from view. Casing 70 may have additional electrical components integrated within such as display 72, button 74, and controller 76 to name but a few. Display 72 can be configured to display any sort of information, for example battery level, power output level, runtime, dose, time, date, etc. Display 72 can be a LCD, LED or other type of display. Button 74 is used to control display 72 and make selections from menus and options that may be displayed.

The FPCB shell 24 can employ electrical contacts on its exterior surface that couple to electrical contacts on the interior of casing 70. The contact coupling allows control of the electrical components inside the FPCB shell 24 via interactions with the outer non-FPCB casing 70. Casing 70 can be comprised of material such as cardboard, wood, paper, plastic, and metal to name but a few. Controller 76 is operatively coupled to FPCB shell 24 to actuate the vaporizer.

Casing 70 has an outer side 78, a distal end 80 and proximal end 82. FPCB 24 can be inserted into casing 70 through aperture 81. In alternative embodiment of the invention, aperture 81 may not extend the length of casing 70, for example two or more casings could be used to envelop FPCB 24, or casing 70 may only partially cover FPCB 24.

Casing 70 can be of any configuration or shape, the embodiment shown represents a typical casing 70. Multi-wrap FPCB 42 could be used in place of single wrap FPCB 24.

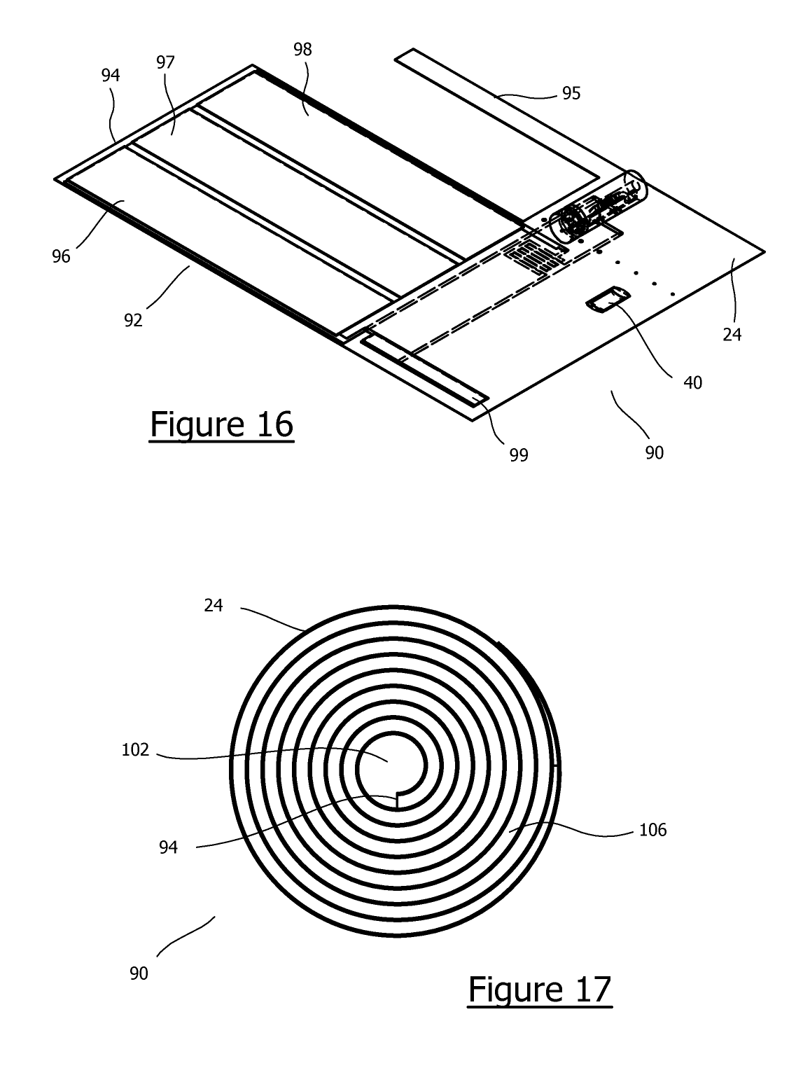

Printed batteries may be incorporated in an electronic personal vaporizer, as shown in FIGS. 16 and 17. There is a multitude of chemistry types of printed batteries that can be employed. Such battery types include Zinc/Manganese-Dioxide, Zinc/air, Zinc/Silver-oxide, Lithium/Manganese-Dioxide, Nickel/Metal-hydride, and Lithium-Ion. This list includes both rechargeable and non-rechargeable types of batteries.

The different battery chemistries used yield different cell voltages, in some cases. The embodiment of an electronic personal vaporizer 90 depicted in FIGS. 16 and 17 demonstrate a Zinc/Manganese-Dioxide printed battery chemistry, which is printed onto the FPCB 24 substrate. The Zinc/Manganese-Dioxide battery has an approximate cell voltage of 1.5 volts. In order to achieve a power source voltage of approximately 4.2 volts, an array of cells 92 is printed. The battery cells 96, 97, 98 in the array 92 have internal resistance and also may possess manufacturing imperfections that may cause a slight decrease in cell voltage when used in series as illustrated in FIG. 16. Cell 96, cell 97, and cell 98 are electrically connected in series and therefore the battery cell array 92 has a theoretical voltage of 4.5 volts. However in application the battery cell array 92 could have, for example, an approximate voltage of 4.2 volts. Although this embodiment depicts a battery cell array 92 of three cells 96, 97, 98 in series, it is known that any number of cells can be used in series and/or parallel configurations to obtain any desired voltage. The battery cell array 92 is electrically coupled to the FPCB 24 circuitry.

Another aspect of the present invention is the incorporation of an integral printed battery and integral printed EL (electroluminescent) light such as an OLED (Organic Light-Emitting Diode). The printed battery and OLED can be printed by various means such as screen printing, offset lithography, transfer-printing, gravure, flexography, and inkjet to name but a few.

The electroluminescent light source, such as an OLED 99, is directly printed onto the FPCB 24 substrate and electrically coupled to the FPCB 24 circuitry. When this embodiment of an electronic personal vaporizer 90 is activated, electrical power from the battery cell array 92 is used to activate the printed OLED 99. The battery array 92 also provides electrical power for use in energizing the atomizer heating element.

The means of activation of electronic personal vaporizer 90, as depicted in FIG. 16, is accomplished with a membrane switch. However it is known that the activation means can be accomplished by other devices such as vacuum switches, vacuum sensors, proximity sensors, pressure sensors, and conductivity sensing to name but a few.

This embodiment also depicts the use of the FPCB 24 substrate utilized to create the proximal end cap for the electronic personal vaporizer. Additional FPCB substrate material 95 may be rolled during assembly and creates an integral proximal end cap for the atomizer section. However it is known that the integral proximal end cap material 95 can be omitted and replaced with the stand-alone proximal end cap 16 of previously described embodiments.

FIG. 16 depicts an embodiment of the present invention in an unfinished, unrolled, flat orientation. FIG. 17 depicts an embodiment of an electronic personal vaporizer 90 with an integral printed battery, similar to the embodiment of FIG. 16, in a rolled orientation. The FPCB 24 substrate is rolled up similar to a “jelly roll” to form several layers. Since the printed battery components 106, such as inks and gels are printed thickly, the rolling of this embodiment produces an almost solid form. Since it is practically not feasible to wrap the inner portion of the roll perfectly tight, a small void 102 results. In alternative embodiments, material may be attached to the FPCB 24 substrate at its edge 94 and used to wind the FPCB 24 substrate around forming the roll. This would then substantially replace the inner void 102 with a core.

In another embodiment of the present invention the printed battery utilizes KOH (Potassium Hydroxide) in the form of a paste like ink that is used as the electrolyte. Furthermore the anode and cathode can be printed onto current collectors that are themselves printed directly onto the FPCB 24 substrate. This would then entail the folding over of the FPCB 24 substrate as to align the anode and cathode on top of each other. A KOH ink with separator properties will be applied between the anode and cathode ink materials. The folded FPCB 24 can then be rolled to complete the fabrication process.

In another embodiment of the invention, the battery may be printed on a FPCB that is not intended to be the main shell of the vaporizer. In such an embodiment the battery is coupled to the FPCB forming the shell of the vaporizer to provide power to the components of the vaporizer.

The printing of the battery is a process of applying chemical compounds to a substrate in the form of inks that include the different components required for a battery. Some typical components are current collector, anode, cathode, electrolyte, and separator. Inks can be formulated to possess the required properties of the battery components. The application of these specially formulated inks in layers mostly on top of each other produce the mechanical structure of the battery.

Electroluminescent light sources are fabricated using either organic or inorganic electroluminescent materials. The active materials are generally semiconductors of wide enough bandwidth to allow exit of the light. A typical OLED is composed of a layer of organic EL materials situated between two electrodes, the anode and cathode, all deposited on the FPCB substrate. Generally speaking, at least one of the electrodes should be optically transparent to allow the light to escape the layered structure. Typically it is the anode that possesses this optically transparent characteristic.

Printing of the battery and EL light source, such as an OLED, onto the FPCB can be accomplished by means of automated processes. The material and labour costs for manufacturing the printed components is significantly less than the stand-alone counterparts used in the typical current state of the art. Overall production quality can be increased by employing automated machinery and processes in place of the manual labour.

The above-described embodiments have been provided as examples, for clarity in understanding the invention. A person with skill in the art will recognize that alterations, modifications and variations may be effected to the embodiments described above while remaining within the scope of the invention as defined by claims appended hereto. As examples, liquid absorbent wadding 20 is shown in the embodiment as a representative of a liquid container for providing liquid to a heating element for vaporization. As a further example the FPCB can be deformed into a shape appropriate for a pipe shaped electronic personal vaporizer.

What is claimed:

1. An electronic personal vaporizer, comprising:
a shell comprising a flexible printed circuit board; and
a printed battery;
wherein the printed battery is printed on the flexible printed circuit board.

2. The electronic personal vaporizer of claim 1 wherein the printed battery is printed onto the flexible printed circuit board via application of inks to the flexible printed circuit board.

3. The electronic personal vaporizer of claim 1 wherein the battery has a chemistry selected from the group consisting of: Zinc and Manganese Dioxide; Zinc and air; Zinc and Silver oxide; Lithium and Manganese Dioxide; Nickel and a metal hydride; and Lithium Ion.

4. The electronic personal vaporizer of claim 1 wherein the battery comprises an electrolyte comprising Potassium Hydroxide.

5. The electronic personal vaporizer of claim 1 further comprising an electroluminescent light source printed on the flexible printed circuit board.

6. The electronic personal vaporizer of claim 5 wherein the electroluminescent light source comprises inorganic electroluminescent materials.

7. The electronic personal vaporizer of claim 5 wherein the electroluminescent light source comprises an organic light-emitting diode

8. The electronic personal vaporizer of claim 7 wherein the organic light emitting diode comprises a layer of organic electroluminescent materials positioned between an anode and a cathode.

9. The electronic personal vaporizer of claim 8 wherein one of the anode and cathode is optically transparent.

10. The electronic personal vaporizer of claim 1 wherein the battery comprises a plurality of cells arranged in an array.

11. The electronic personal vaporizer of claim 10 wherein the array of cells is configured in series.

12. A method of manufacturing an electronic personal vaporizer comprising:
providing a flexible printed circuit board to serve as a shell for the vaporizer;
providing a plurality of battery components applied to the flexible printed circuit board,
shaping the flexible printed circuit board around the battery components to form a battery and to operatively couple the battery to the flexible printed circuit board.

13. The method of claim 12 wherein the battery components are printed by applying chemicals compounds in ink on the flexible printed circuit board.

14. The method of claim 12 wherein the battery components include an anode and a cathode.

15. The method of claim 13 wherein the flexible printed circuit board comprises a current collector, and the anode and cathode are printed on the current collector such that when the flexible printed circuit board is shaped, the anode and cathode align.

16. The method of claim 13 wherein the shell is shaped by rolling the flexible printed circuit board around the components.

17. The method of claim 13 wherein the shell is shaped by folding the flexible printed circuit board around the components.

18. The method of claim 16 wherein a material is attached to an edge of the flexible printed circuit board and the flexible printed circuit board is rolled around the material.

19. The method of claim 18 wherein the flexible printed circuit board is stabilised by use of heat melting.

20. The method of claim 19 wherein the flexible printed circuit board is stabilised by use of fasteners.

21. An electronic personal vaporizer, comprising:
a shell comprising a flexible printed circuit board; and
a printed battery;
wherein the printed battery is operatively coupled to the flexible printed circuit board.
